(19) United States
(12) Patent Application Publication
(10) Pub. No.: US 2013/0068160 A1
(43) Pub. Date: Mar. 21, 2013

(54) EVAPORATION DEVICE AND EVAPORATION APPARATUS

(71) Applicants: Ching-Chiun Wang, Miaoli County (TW); Chih-Yung Huang, Taichung City (TW); Chien-Chih Chen, Taichung City (TW); Szu-Hao Chen, Changhua County (TW); Fu-Ching Tung, Hsinchu City (TW); Atsushi Oda, Kawasaki (JP)

(72) Inventors: Ching-Chiun Wang, Miaoli County (TW); Chih-Yung Huang, Taichung City (TW); Chien-Chih Chen, Taichung City (TW); Szu-Hao Chen, Changhua County (TW); Fu-Ching Tung, Hsinchu City (TW); Atsushi Oda, Kawasaki (JP)

(73) Assignee: INDUSTRIAL TECHNOLOGY RESEARCH INSTITUTE, Hsinchu (TW)

(21) Appl. No.: 13/471,462

(22) Filed: May 15, 2012

(30) Foreign Application Priority Data
Sep. 20, 2011 (TW) 100133745

(51) Int. Cl. C23C 16/448; C23C 16/04

(52) U.S. Cl. 118/720

(57) ABSTRACT

An evaporation device and an evaporation apparatus applying the same are adapted to performing evaporation process to an object to be coated. The evaporation device includes a tape carrier and a mask. The tape carrier has a heating region. The object to be coated is located over the heating region and is adapted to move along a feeding direction. The tape carrier is adapted to carry a coating material to pass through the heating region. The coating material is heated in the heating region and evaporated. The mask having an opening between the heating region and the object to be coated is disposed in the periphery of the heating region. The evaporated coating material is adapted to pass through the opening and coated on the object.

### CROSS-REFERENCE TO RELATED APPLICATION

This application claims the priority benefit of Taiwan application serial no. 100133745, filed on Sep. 20, 2011. The entirety of the above-mentioned patent application is hereby incorporated by reference herein and made a part of this specification.

### BACKGROUND OF THE INVENTION

1. Technical Field

The disclosure relates to a fabrication equipment, and more particularly, to an evaporation equipment adapted to perform an evaporation process.

2. Description of Related Art

Coating technology mainly includes physical vapor deposition (PVD) and chemical vapor deposition (CVD). The former technology utilizes physical phenomenon to perform thin film deposition and the latter technology utilizes chemical reactions to perform thin film deposition. The current trend for physical vapor deposition is through evaporation and sputtering. The two technologies commonly use a physical phenomenon method to perform thin film deposition. Regarding evaporation, the main theory is to heat the evaporation object, and use the saturated evaporation pressure when the evaporation object is under high temperature (near melting point) to deposit the thin film.

The application of the evaporation technology is widely used. For example, an organic electro-luminescence device of popular display elements can further adopt evaporation technology to fabricate organic compound layers. However, current evaporation technology still has problems such as difficulty in fabricating large area components, damaging material because of high temperature, uneven film thickness from evaporation, and low material utilization.

FIG. 1 illustrates a conventional evaporation apparatus, wherein a crucible 102 contains coating material, and a heater is located below a bottom of the crucible 102 to heat the coating material. The coating material that is evaporated will pass through a transmitting channel 104 and is ejected through a nozzle 106, to be coated on an object. However, the conventional evaporation apparatus needs to heat the entire coating material, causing the coating material in the crucible 102 to maintain a high temperature, to continually deposit film on the object to be coated. Thus, the coating material is prone to be damaged when under high temperature for a long time, and the composition of the coating material may change, affecting the process yield. In addition, the nozzle 106 that ejects the coating material has a spread angle, which may cause unevenness in coating, thereby lowering material utilization. Furthermore, as coating material is placed in the crucible 102, when the coating material is used up, more coating material can be added only after the entire process is stopped. This causes inconvenience, and limits the improvement of production efficiency.

### SUMMARY OF THE INVENTION

The disclosure provides an evaporation device, adapted to perform an evaporation process to an object to be coated. The evaporation device includes a tape carrier and a mask. The tape carrier has a heating region. The objected to be coated is located over the heating region and is adapted to move along a feeding direction. The tape carrier is adapted to carry a coating material passing through the heating region. The coating material is heated in the heating region and evaporated. The mask is disposed in the periphery of the heating region, and has an opening located between the heating region and the object to be coated. The evaporated coating material is adapted to pass through the opening and coated on the object.

The disclosure further provides an evaporation apparatus, including a plurality of the aforementioned evaporation devices. The evaporation devices are disposed side by side, so as to perform evaporation towards an object to be coated, and form a plurality of coating layers stacked on each other on the object to be coated.

Based on the above, the disclosure provides an evaporation device and an evaporation apparatus using the evaporation device that carries out a continuous production flow through a tape carrier, to have high production efficiency. In addition, the evaporation device and the evaporation apparatus of the disclosure performs partial heating towards the coating material in the heating region. This prevents the coating material from being damaged or changing in composition after staying in a high temperature state. Furthermore, the evaporation device and the evaporation apparatus of the disclosure can effectively control the evaporation angle of the coating material through the mask, to improve the uniformity of the coating.

Several exemplary embodiments accompanied with figures are described in detail below to further describe the disclosure in detail.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 illustrates a conventional evaporation apparatus.

FIG. 2 illustrates an evaporation device according to an embodiment of the disclosure.

FIG. 3 to FIG. 5 respectively illustrates evaporation devices of the disclosure adopting plates of different shapes to form a mask.

FIG. 6 to FIG. 8 respectively illustrates modified evaporation devices based on the evaporation devices of FIG. 3 to FIG. 5.

FIG. 9 to FIG. 11 respectively illustrates other modified evaporation devices based on the evaporation devices of FIG. 3 to FIG. 5.

FIG. 12 illustrates an evaporation apparatus performing evaporation towards an object to be coated using the evaporation device of FIG. 2.

FIG. 13 illustrates a substrate having stacked film layers formed by the evaporation apparatus of FIG. 12.

FIG. 14 to FIG. 16 respectively illustrates evaporation devices of the disclosure adopting tape carriers of different designs.

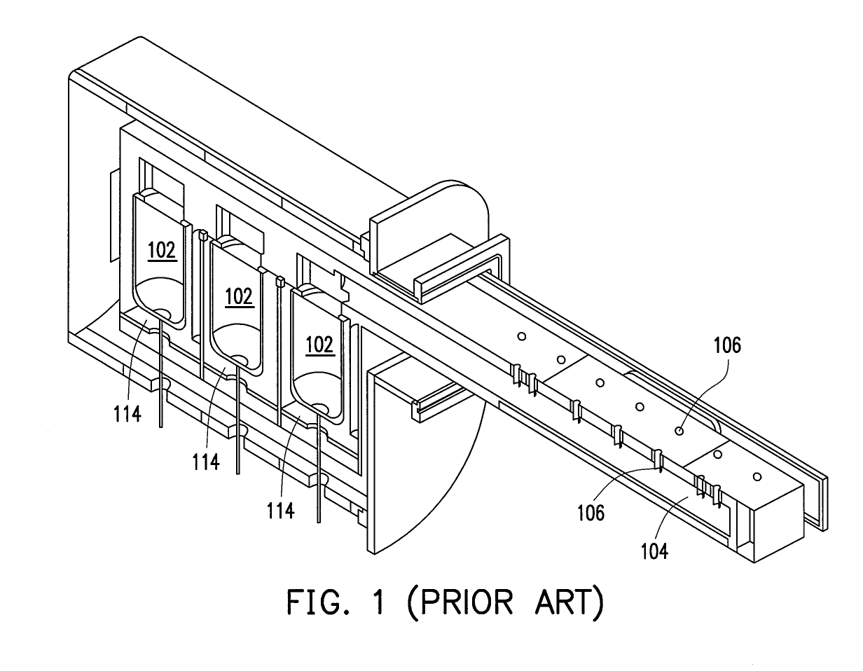

### DESCRIPTION OF EMBODIMENTS

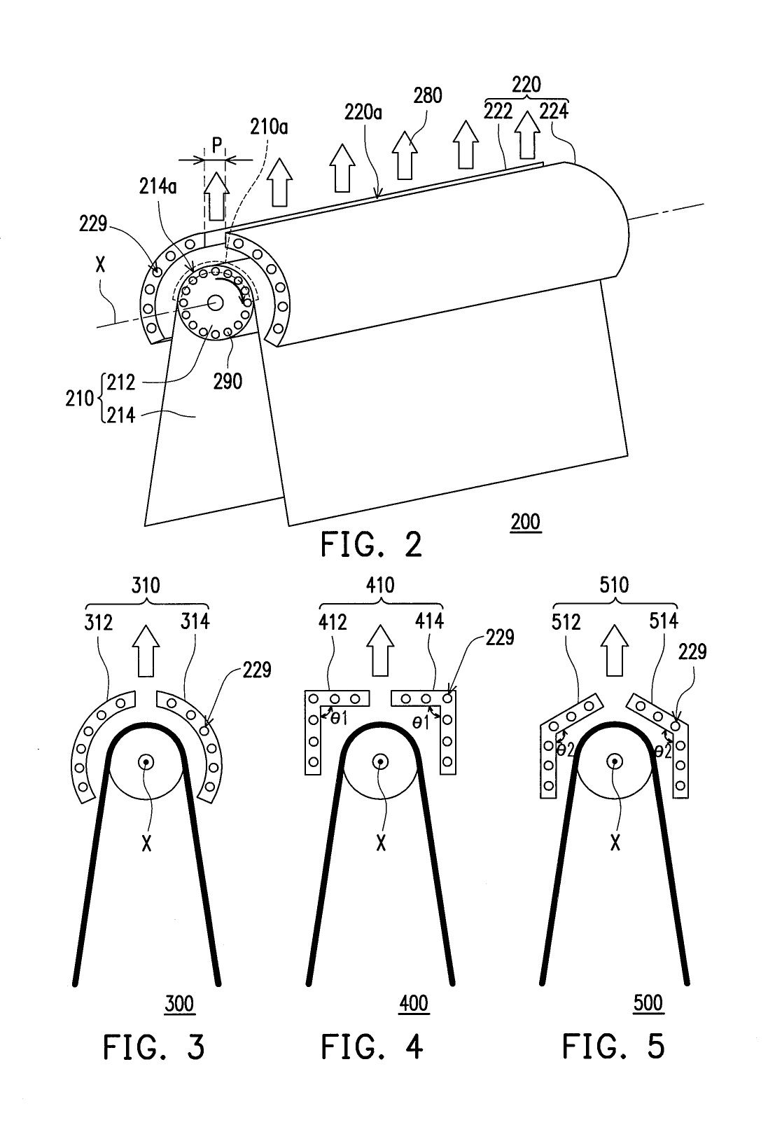

FIG. 2 illustrates an evaporation device according to an embodiment of the disclosure. Referring to FIG. 2, an evaporation device 200 mainly includes a tape carrier 210 and a mask 220. The tape carrier 210 mainly provides a heating region 210a, and is adapted to carry a coating material to pass through the heating region 210a. This way, the coating material is heated in the heating region 210a, causing the coating material to evaporate. In an exemplary embodiment, the tape carrier 210 includes a heating shaft 212 and a tape 214. The heating shaft 212 is adapted to rotate along an axial direction X. The heating shaft 212 will emit heat, and the inside structure of the heating shaft includes, for example, a hot filament 290 or adopts an infrared heating method. The tape 214 is propped against a side of the heating shaft 212, and the tape 214 is adapted to wrap around the heating shaft 212. In addition, the tape 214 includes a carrying surface 214a facing away from the heating shaft 212, and is adapted to carry the coating material. Herein, the region where the heating shaft 212 and the tape 214 contacts is the heating region 210a. When the tape 214 carries the coating material to pass through the heating region 210a, the heating shaft 212 will heat the coating material to a vapor state partitioned by the tape 214.

The mask 220 is disposed in a periphery of the heating region 210a. The mask 220 has an opening 220a located above the heating region 210a. The evaporated coating material 280 is adapted to pass through the opening 220a to be coated on the object. The opening 220a of the embodiment is, for example, a slit shaped slot that extends along the axial direction X from an end of the tape carrier 210 to the other end of the tape carrier 210. In detail, the mask 220 of the embodiment is formed by two plates 222 and 224. The two plates 222 and 224 are symmetrically disposed on the two opposite sides of the heating region 210a. The two plates 222 and 224 maintain a gap P above the heating region 210a, forming the opening 220a.

The embodiment does not limit the shape of the mask 220. The plates 222 and 224 forming the mask 220 can be any shape designed according to need. FIG. 3 to FIG. 5 respectively illustrates evaporation devices adopting plates of different shapes to form a mask. The mask 310 used by the evaporation device 300 of FIG. 3 is formed by two plates 312 and 314. The cross-section of the plates 312 and 314 perpendicular to the axial direction X are C shaped. In addition, the mask 410 used by the evaporation device 400 of FIG. 4 is formed by two plates 412 and 414. The cross-section of the plates 412 and 414 perpendicular to the axial direction X are L shaped. The angle 01 of the plates 412 and 414 is close to a right angle. Furthermore, the mask 510 used by the evaporation device 500 of FIG. 5 is formed by two plates 512 and 514. The cross-section of the plates 512 and 514 perpendicular to the axial direction X are L shaped. The angle θ2 of the plates 512 and 514 is an obtuse angle.

Referring to FIG. 2 to FIG. 5, the mask 220 of the embodiment can include a cooling unit, such as the holes 229 passing through the mask 220, wherein the holes 229 are substantially parallel to the axial direction X. The holes 229 can be filled with cooling mediums such as air, water, or refrigerant.

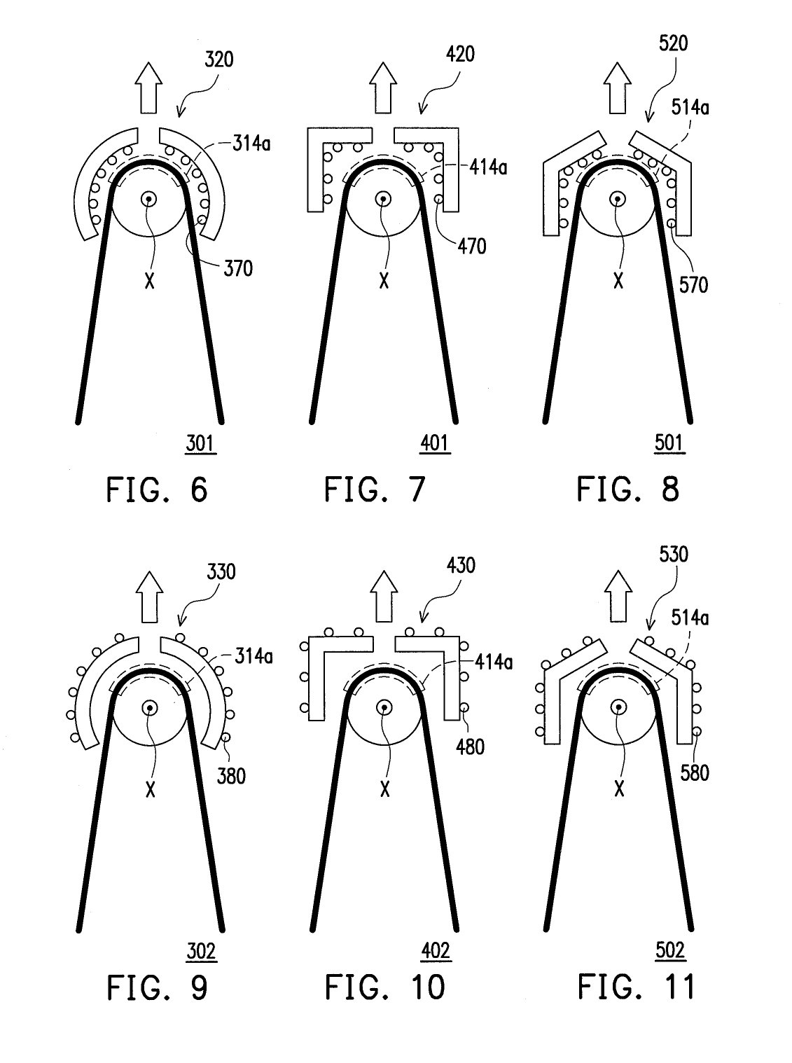

Of course, the disclosure does not limit the type of the cooling unit. For example, the disclosure is not limited to the aforementioned embodiment with holes 229 disposed in the mask 220, to provide a cooling effect. In other embodiments, a cooling passage can be selectively moved to the external portion of the mask, such as the surface of the mask 220. Using the different types of masks of the evaporation devices shown in FIGS. 3 to 5 as examples, as shown in FIGS. 6 to 8, a plurality of cooling pipes 370 can be disposed on a side of the mask 320 used to face the heating region 314a; a plurality of cooling pipes 470 can be disposed on a side of the mask 420 used to face the heating region 414a; or a plurality of cooling pipes 570 can be disposed on a side of the mask 520 used to face the heating region 514a. The evaporation devices 301, 401, 501 of FIGS. 6 to 8 are respectively similar to the evaporation devices 300, 400, 500 of FIGS. 3 to 5. The identical or similar components will not be repeated herein.

In addition, using the different types of masks of the evaporation devices shown in FIGS. 3 to 5 as examples, as shown in FIGS. 9 to 11, a plurality of cooling pipes 380 can be disposed on a side of the mask 330 not facing the heating region 314a; a plurality of cooling pipes 480 can be disposed on a side of the mask 430 not facing the heating region 414a; or a plurality of cooling pipes 580 can be disposed on a side of the mask 530 not facing the heating region 514a. The evaporation devices 301, 401, 501 of FIGS. 9 to 11 are respectively similar to the evaporation devices 300, 400, 500 of FIGS. 3 to 5. The identical or similar components will not be repeated herein.

In the aforementioned embodiments, the cooling pipes 370, 380, 470, 480, 570, 580 are substantially parallel to the axial direction X, and the cooling pipes 370, 380, 470, 480, 570, 580 can be filled with cooling mediums such as air, water or refrigerant.

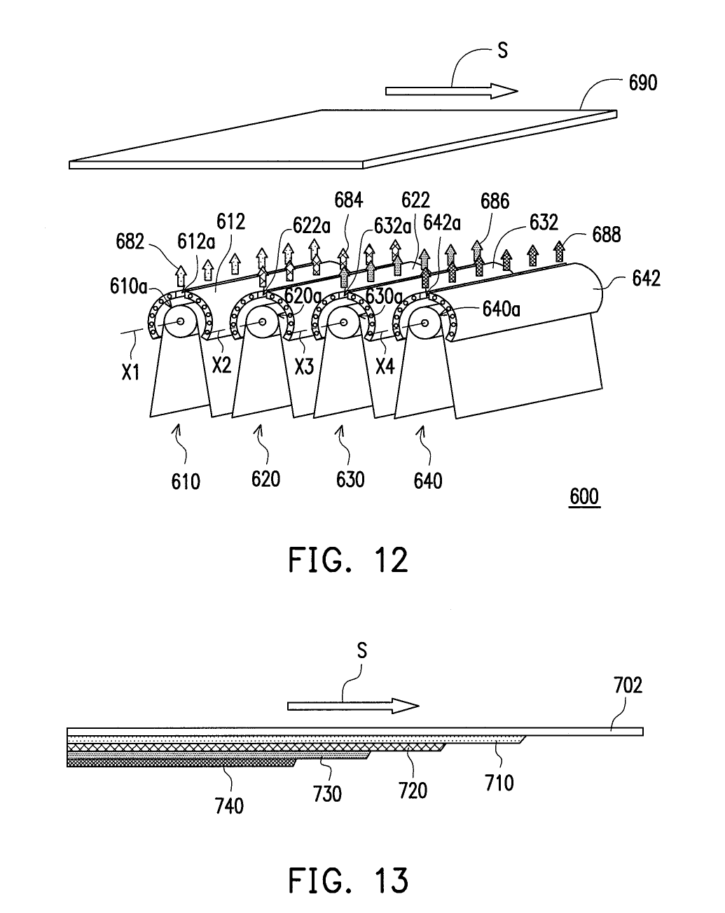

FIG. 12 illustrates an evaporation apparatus performing evaporation towards an object to be coated using the evaporation device of FIG. 2. As seen in FIG. 12, the evaporation apparatus 600 has a plurality of the aforementioned evaporation devices 610 to 640, and is used to perform evaporation towards an object to coated 690, to form a plurality of coating layers stacked on each other on the object to be coated 690. The object 690 to be coated is located over the heating regions 610a to 640a, and is adapted to move along a feeding direction S. The evaporation devices 610 to 640 are disposed side by side, and the axial directions X1 to X4 of the evaporation devices 610 to 640 are substantially parallel. Generally speaking, the evaporation process will be performed in a low pressure or vacuum environment. The low pressure or vacuum environment is mainly made up of an evaporation chamber and a vacuum system used to provide the vacuum required for evaporation. The evaporation devices 610 to 640 and the object 690 to be coated are placed in the evaporation chamber.

In the exemplary embodiment, the moving direction S of the object 690 to be coated is substantially perpendicular to the axial directions X1 to X4 of the evaporation devices 610 to 640. The openings 612a to 642a of the masks 612 to 642 of each evaporation device 610 to 640 is located between the heating regions 610a to 640a and the object 690 to be coated. This causes the evaporated coating material of each evaporation device 610 to 640 to pass through the corresponding opening 612a to 642a and be coated on the object 690 to be coated.

The evaporation apparatus 600 of the embodiment can perform a large area and continuous evaporation process. For example, the evaporation process can be used in the fabrication of organic electro-luminescence device, to form organic compound layers such as a hole injection layer, a hole transport layer, a light emitting layer, an electron transporting layer, and an electron injection layer on a substrate of the object 690 to be coated.

FIG. 13 illustrates a substrate having stacked film layers formed by the evaporation apparatus 600. Please refer to FIG. 12 and FIG. 13. In detail, the tape carriers 614 to 644 of the evaporation devices 610 to 640 of the embodiment can respectively carry and heat different coating materials 682 to 688, such as the materials of the aforementioned organic compound layers. When the evaporation devices 610 to 640 are disposed side by side as shown in FIG. 12, and a substrate 702 (object 690 to be coated) moves in the feeding direction S to pass the top of the evaporation devices 610 to 640, each organic compound material will be formed on the substrate 702 layer by layer. For example, the evaporation device 610 will coat a coating material 682 onto the substrate 702, and form an organic compound layer 710; a coating material 684 of the evaporation device 620 will be coated onto the organic compound layer 710, to form an organic compound layer 720; a coating material 686 of the evaporation device 630 will be coated onto the organic compound layer 720, to form an organic compound layer 730; and a coating material 688 of the evaporation device 640 will be coated onto the organic compound layer 730, to form an organic compound layer 740.

The tape 214 of the tape carrier 210 of the aforementioned embodiment is, for example, a continuous flexible band object, and is driven by the heating shaft 212. The tape 214 continuously provides coating material to the heating region 210a, so as to continuously perform evaporation. On the other hand, the tape carrier can further be amended, to achieve a continuous feeding of material. The following provides descriptions of different designs that achieve the same or similar effects.

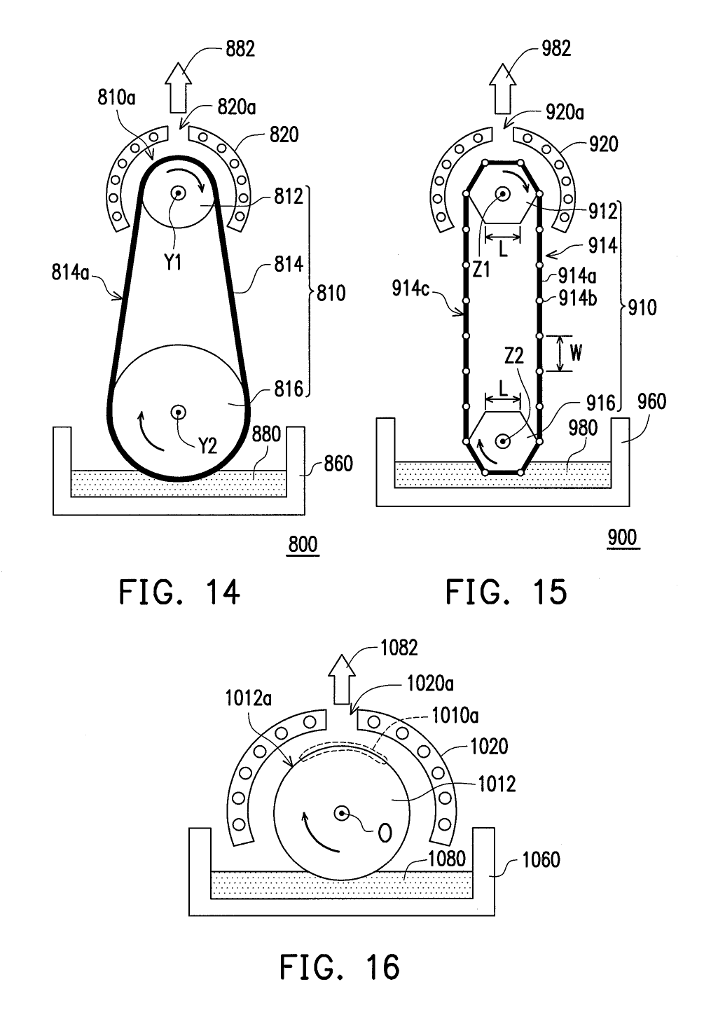

According to other embodiments of the disclosure, FIG. 14 to FIG. 16 respectively illustrates evaporation devices adopting tape carriers of different designs. Herein, the evaporation devices of FIGS. 14 to 16 will be described through the differences between the previous embodiments. Similar portions can be referenced above, and will not be repeated herein.

The tape 814 of the tape carrier 810 of FIG. 14 is a closed tape. The tape carrier 810 includes a heating shaft 812 and an auxiliary shaft 816. The heating shaft 812 and the auxiliary shaft 816 are substantially parallel to each other and respectively rotate according to parallel axial directions Y1 and Y2 (perpendicular to the figure surface). The heating shaft 812 and the auxiliary shaft 816 are both circular shafts. That is to say, a cross section of the heating shaft 812 perpendicular to the axial direction Y1 and a cross section of the auxiliary shaft 816 perpendicular to the axial direction Y2 are both circular. The tape 814 carries and wraps around the heating shaft 812 and the auxiliary shaft 816. In addition, the evaporation device 800 of FIG. 14 further includes a material trench 860, used to contain the coating material 880 in liquid state. The portion of the tape 814 supported by the auxiliary shaft 816 is adapted to submerge in the coating material 880 in liquid state, so that the coating material 880 in liquid state is attached to a carrying surface 814a of the tape 814. The solvent of the coating material 880 may vaporize and the coating material 880 becomes solid as the heating shaft 812 and the auxiliary shaft 816 rotate. After the solid coating material 880 passes through the heating region 810a, it will be evaporated to a vapor state, and will be ejected through an opening 820a of the mask 820.

The tape 914 of the tape carrier 910 of FIG. 15 is a track formed through a plurality of sheet objects 914a pivotally connected to each other. Two adjacent sheet objects 914a are connected through a pivot shaft 914b. The tape carrier 910 further includes a heating shaft 912 and an auxiliary shaft 916 which are substantially parallel to each other and respectively rotate according to parallel axial directions Z1 and Z2 (perpendicular to the figure surface). In addition, a rotating direction of the pivot shafts 914b is substantially parallel to the axial directions Z1 and Z2. The heating shaft 912 and the auxiliary shaft 916 are both polygonal shafts. That is to say, a cross section of the heating shaft 912 perpendicular to the axial direction Z1 and a cross section of the auxiliary shaft 916 perpendicular to the axial direction Z2 are both polygonal. A side length L of each side of the polygon is substantially equal to a width W of each sheet object 914a. Thus, the heating shaft 912 and the auxiliary shaft 916 can be used to drive the tape 914. The evaporation device 900 further includes a material trench 960, used to contain the coating material 980 in liquid state. The portion of the tape 916 supported by the auxiliary shaft 914 is adapted to submerge in the coating material 980 in liquid state, so that the liquid state of the coating material 981 is attached to a carrying surface 914c of the tape 914. The solvent of the coating material 980 may vaporize and the coating material 980 becomes solid as the heating shaft 912 and the auxiliary shaft 916 rotate. After the solid coating material 980 passes through the heating region 910a, it will be evaporated to a vapor state, and will be ejected through an opening 920a of the mask 920.

The tape carrier of FIG. 16 omits a tape, and directly uses the heating shaft 1012 to carry and heat the coating material. In detail, the heating shaft 1012 is adapted to rotate along an axial direction O. A material trench 1060 contains the coating material 1080 in liquid state, and a portion of the heating shaft 1012 is adapted to submerge in the coating material 1080 in liquid state, so that the coating material 1080 in liquid state is attached to the surface 1012a of the heating shaft 1012. In addition, the heating region 1010a is located above the surface 1012a of the heating shaft 1012. The solvent of the coating material 1080 may vaporize and the coating material 1080 becomes solid as the heating shaft 1012 rotates. After the solid coating material 1080 passes through the heating region 1010a, enough heat will be absorbed by the solid coating material 1080 so that it will be evaporated to a vapor state, and will be ejected through an opening 1020a of the mask 1020.

To sum up, the disclosure provides an evaporation device and an evaporation apparatus using the evaporation device that carries out a large area and continuous evaporation process through a tape carrier, to assist in raising production efficiency. In addition, since the tape carrier only performs partial heating towards the coating material in the heating region, this prevents the coating material from being damaged or changing in composition after staying in a high temperature state, thereby reducing production cost. Also, in the embodiments, a mask is disposed between the heating region and the object to be coated, to limit the angle of the evaporated coating material passing through the openings. This effectively controls the coating areas, improving the uniformity of coating. The mask can also prevent contamination from the coating material of adjacent evaporation devices, which improves process yield.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An evaporation device, adapted to perform an evaporation process to an object to be coated, the evaporation device comprising:
a tape carrier, having a heating region, wherein the object to be coated is located over the heating region and is adapted to move along a feeding direction, and the tape carrier comprises:
a heating shaft, having a surface, wherein the heating shaft is adapted to rotate along an axial direction, and the object to be coated is located on a side of the heating shaft; and
a tape, propped against the side of the heating shaft, wherein the tape is adapted to wrap around the heating shaft, and the tape has a carrying surface facing away from the heating shaft, adapted to carry a coating material to pass through the heating region, so as to heat the coating material in the heating region through the heating shaft, causing the coating material to be evaporated; and
a mask, disposed in a periphery of the heating region, wherein the mask has an opening located between the heating region and the object to be coated, and the evaporated coating material is adapted to pass through the opening to be coated on the object.

2. The evaporation device as claimed in claim 1, further comprising an auxiliary shaft, the heating shaft and the auxiliary shaft being substantially parallel and respectively carrying the tape, wherein the tape is a closed tape, wrapping around the heating shaft and the auxiliary shaft.

3. The evaporation device as claimed in claim 1, wherein the tape is a continuous flexible band object.

4. The evaporation device as claimed in claim 3, wherein the heating shaft comprises a cross section perpendicular to the axial direction, and the cross section is circular.

5. The evaporation device as claimed in claim 1, wherein the tape is a track formed through a plurality of sheet objects pivotally connected to each other, and a pivot shaft between two adjacent sheet objects is substantially parallel to the axial direction.

6. The evaporation device as claimed in claim 5, wherein the heating shaft comprises a cross section perpendicular to the axial direction, the cross section is a polygon, and a side length of the polygon is substantially equal to a width of each sheet object.

7. The evaporation device as claimed in claim 1, wherein the opening comprises a slot, and the slot extends along the axial direction from an end of the tape carrier to the other end of the tape carrier.

8. The evaporation device as claimed in claim 1, wherein the mask comprises two plates, symmetrically disposed on the two opposite sides of the heating region, and the two plates maintain a gap above the heating region, forming the opening.

9. The evaporation device as claimed in claim 8, wherein a cross section of each plate perpendicular to the axial direction is C-shaped or L-shaped.

10. The evaporation device as claimed in claim 1, wherein the mask comprises a cooling unit.

11. The evaporation device as claimed in claim 10, wherein the cooling unit comprises a plurality of holes passing through the mask.

12. The evaporation device as claimed in claim 11, wherein the holes are substantially parallel to the axial direction.

13. The evaporation device as claimed in claim 11, further comprising a cooling medium, located in the holes.

14. The evaporation device as claimed in claim 10, wherein the cooling unit comprises a plurality of cooling pipes located on a surface of the mask.

15. The evaporation device as claimed in claim 14, wherein the cooling pipes are located on a side of the mask facing towards the heating region.

16. The evaporation device as claimed in claim 14, wherein the cooling pipes are located on a side of the mask facing away from the heating region.

17. The evaporation device as claimed in claim 14, wherein the cooling pipes are substantially parallel to the axial direction.

18. The evaporation device as claimed in claim 14, further comprising a cooling medium, located in the cooling pipes.

19. The evaporation device as claimed in claim 1, wherein the moving direction of the object to be coated is substantially perpendicular to the axial direction.

20. An evaporation apparatus, including a plurality of evaporation devices of claim 1, wherein the evaporation devices are disposed side by side, so as to perform evaporation towards an object to be coated, and form a plurality of coating layers stacked on each other on the object to be coated.
